(19) United States
(12) Patent Application Publication
(10) Pub. No.: US 2006/0080825 A1
(43) Pub. Date: Apr. 20, 2006

(54) Methods related to electromagnetic interference shielding

(76) Inventor: James D. Pille, Ashley, IL (US)

Correspondence Address: Anthony G. Fussner, Suite 400, 7700 Bonhomme, St. Louis, MO, 63105, US

(21) Appl. No.: 11/209,989

(22) Filed: Aug. 23, 2005

Related U.S. Application Data
(60) Provisional application No. 60/618,622, filed on Oct. 14, 2004.
(60) Provisional application No. 60/618,620, filed on Oct. 14, 2004.

(51) Int. Cl. H05K 9/00; B23P 17/04

(52) U.S. Cl. 29/592; 174/35 GC; 277/920

(57) ABSTRACT

In one implementation, a method of shielding against ingress and egress of electromagnetic energy relative to an electronic device housing generally includes selecting a color from a plurality of colors for an aesthetically colored portion of at least one electromagnetic interference (EMI) shield. The EMI shield is coupled to the electronic device housing such that the aesthetically colored portion is visible external to the housing.

### CROSS-REFERENCE TO RELATED APPLICATIONS

This application claims the benefit of U.S. Provisional Application No. 60/618,622 filed Oct. 14, 2004. This application also claims the benefit of U.S. Provisional Application No. 60/618,620 filed Oct. 14, 2004. The disclosures of the above applications are incorporated herein by reference.

### FIELD

The invention generally relates to electromagnetic interference (EMI) shielding, and more particularly (but not exclusively) to methods related to EMI shielding with aesthetically colored EMI shields.

### BACKGROUND

During normal operation, electronic equipment can generate undesirable electromagnetic energy that can interfere with the operation of proximately located electronic equipment due to electromagnetic interference (EMI) transmission by radiation and conduction. The electromagnetic energy can be of a wide range of wavelengths and frequencies. To reduce the problems associated with EMI, sources of undesirable electromagnetic energy may be shielded and electrically grounded. Shielding can be designed to prevent both ingress and egress of electromagnetic energy relative to a housing or other enclosure in which the electronic equipment is disposed. Since such enclosures often include gaps or seams between adjacent access panels and around doors and connectors, effective shielding can be difficult to attain because the gaps in the enclosure permit transference of EMI therethrough. Further, in the case of electrically conductive metal enclosures, these gaps can inhibit the beneficial Faraday Cage Effect by forming discontinuities in the conductivity of the enclosure which compromise the efficiency of the ground conduction path through the enclosure. Moreover, by presenting an electrical conductivity level at the gaps that is significantly different from that of the enclosure generally, the gaps can act as slot antennae, resulting in the enclosure itself becoming a secondary source of EMI.

An area of concern in electronic enclosures such as personal computers and the like, which connect to peripheral equipment, is the zone surrounding electrical connectors and electrical connections, generally referred to as an input/output (“I/O”) panel. Cutouts and other access are provided in a bezel in the enclosure to facilitate connection of cabling which connect a computer processor to a printer, a display, a keyboard, and other related equipment. The connector sockets are typically mounted on an I/O panel back plane of a printed circuit board. As with other gaps in the enclosure, these cutouts are preferably shielded with an EMI shield.

EMI shields have been developed for use in gaps and around doors to provide a degree of EMI shielding while permitting operation of enclosure doors and access panels and fitting of connectors. To shield EMI effectively, the shield should be capable of absorbing or reflecting EMI as well as establishing a continuous electrically conductive path across the gap in which the shield is disposed. Conventional metallic shields manufactured from copper doped with beryllium are widely employed for EMI shielding due to their high level of electrical conductivity. Due to inherent electrical resistance in the shield, a portion of the electromagnetic field being shielded induces a current in the shield, requiring that the shield form a part of an electrically conductive path for passing the induced current flow to ground. Failure to ground the shield adequately could result in radiation of an electromagnetic field from a side of the shield opposite the primary EMI field.

### SUMMARY

In one implementation, a method of shielding against ingress and egress of electromagnetic energy relative to an electronic device housing generally includes selecting a color from a plurality of colors for an aesthetically colored portion of at least one electromagnetic interference (EMI) shield. The EMI shield is coupled to the electronic device housing such that the aesthetically colored portion is visible external to the housing.

In another implementation, a method of shielding against ingress and egress of electromagnetic energy relative to an electronic device housing generally includes coupling to the electronic device housing at least one electromagnetic interference (EMI) shield having an aesthetically colored portion such that the aesthetically colored portion is visible external to the housing. The aesthetically colored portion substantially reflects light having a frequency within a predetermined range so as to color coordinate with light being substantially reflected by adjacent external structure of the electronic device housing.

In another implementation, a method of customizing an electronic device housing generally includes decorating the electronic device housing with at least one color-coordinated electromagnetic interference (EMI) shield coupled to the housing such that an aesthetically colored portion of the EMI shield is visible external to the housing.

Further areas of applicability of the invention will become apparent from the detailed description provided hereinafter. It should be understood that the detailed description and specific examples, while indicating preferred embodiments of the invention, are intended for purposes of illustration only and are not intended to limit the scope of the invention.

### BRIEF DESCRIPTION OF THE DRAWINGS

The invention will become more fully understood from the detailed description and the accompanying drawings, wherein:

FIG. 1 is a front perspective view of an aesthetically colored EMI shield according to one embodiment of the invention;

FIG. 2 is a rear perspective view of the EMI shield shown in FIG. 1;

FIG. 3 is a cross-sectional view of the EMI shield taken along line 3-3 in FIG. 1;

FIG. 4 is a front perspective view of an aesthetically colored EMI shield according to another embodiment of the invention;

FIG. 5 is a rear perspective view of the EMI shield shown in FIG. 4;

FIG. 6 is a front perspective view of an aesthetically colored EMI shield according to another embodiment of the invention;

FIG. 7 is a rear perspective view of the EMI shield shown in FIG. 6;

FIG. 8 is a front perspective view of an aesthetically colored EMI shield according to another embodiment of the invention;

FIG. 9 is a rear perspective view of the EMI shield shown in FIG. 8;

FIG. 10 is a front schematic plan view of an aesthetically colored EMI shield according to another embodiment of the invention;

FIG. 11 is a cross-sectional view of the EMI shield shown in FIG. 10 taken along 10-10 in FIG. 10;

FIG. 12 is a cross-sectional view of an aesthetically colored EMI shield according to another embodiment of the invention; and

FIG. 13 is a flow chart of an exemplary process for manufacturing an aesthetically colored EMI shield according to one implementation of the invention.

### DETAILED DESCRIPTION OF THE EXEMPLARY EMBODIMENTS

The following description of the exemplary embodiments is merely exemplary in nature and is in no way intended to limit the invention, its application, or uses.

According to various aspects, the invention provides aesthetically colored electromagnetic interference (EMI) shields such as EMI gaskets. At least a portion of the EMI shield is aesthetically colored and configured to substantially reflect light having a frequency within a predetermined range so as to color coordinate (e.g., match or contrast with the color of depending, for example, on the customer requirements, etc.) with light being substantially reflected by adjacent external structure of an electronic equipment housing. The aesthetically colored portion is visible external to the electronic equipment housing when the EMI shield is operatively engaged with the electronic equipment housing.

The color for the aesthetically colored portion can be selected from a wide range of colors, for example, depending on the user's preferences. For example, the aesthetically colored portion can be selectively configured to substantially reflect light having a frequency within a predetermined range so as to match in color with the light being substantially reflected by the adjacent external structure of the electronic equipment housing. Alternatively, the aesthetically colored portion can be selectively configured to substantially reflect light having a frequency within a predetermined range so as to contrast in color with light being substantially reflected by the adjacent external structure of the electronic equipment housing.

Accordingly, aspects of the invention allow for customization or personalization of the electronic device housing by allowing a user to select a color for the aesthetically colored portion of the EMI shield so as to color-coordinate with the housing, or at least portion thereof, to which the EMI shield will be operatively engaged. This can be especially advantageous given the increasing popularity of variously colored (e.g., red, blue, green, etc.) computer gaming consoles and in the Information Technology and Telecommunications where peripheral connections are commonly located in the view of the operator. With various implementations of the present invention, the aesthetically colored portion can be colored so as to at least substantially match or blend in with the color of the electronics enclosure so as to make the EMI shield less visible. In comparison, traditional EMI gaskets are commonly provided such that the natural metallic luster of the final plating component creates a metallic luster outline that is readily visible in contrast to the color of the electronics enclosure.

In certain embodiments, an electronic equipment housing may include more than aesthetically colored EMI shield of the present invention. In which case, the user may select different colors for the different EMI shields so as to personalize or provide the housing with a particular motif, such as red, white and blue patriotic motif.

In yet other aspects, the invention provides electronics enclosures, housings, electronic devices, and electronic equipment that include at least one of such aesthetically colored EMI shields.

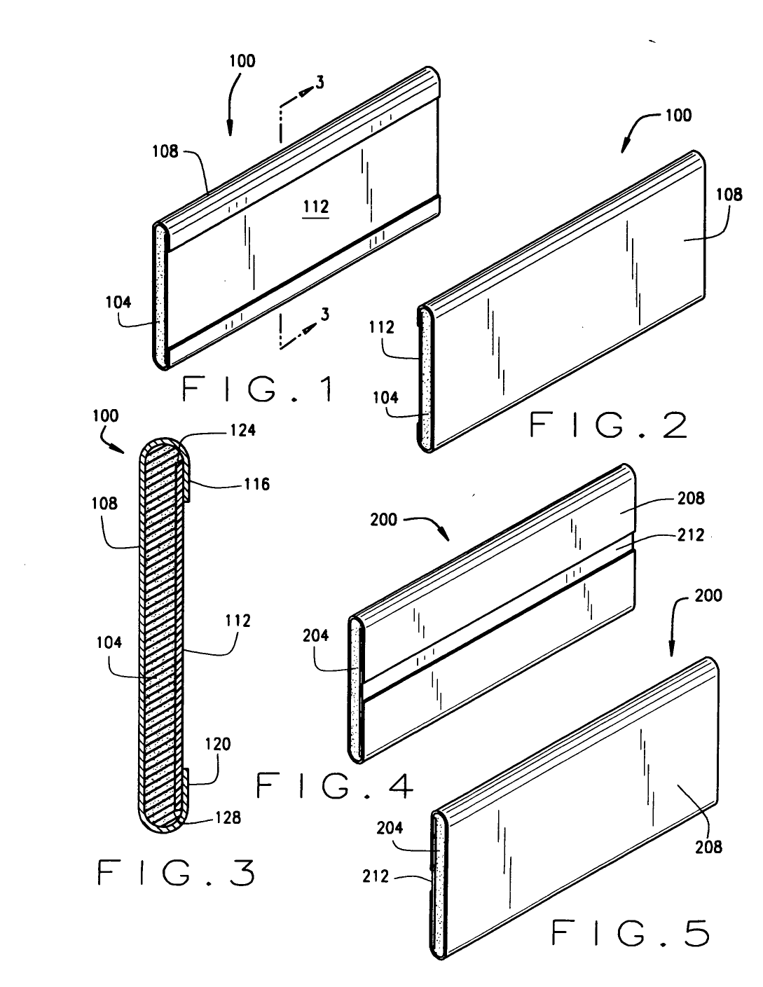

FIGS. 1 through 3 illustrate an exemplary aesthetically colored EMI shield 100 in accordance with the principles of this invention. As shown, the EMI shield 100 includes a core 104, an electrically conductive portion 108, and an aesthetically colored portion 112.

In this particular embodiment, the core 104, electrically conductive portion 108, and aesthetically colored portion 112 are shown as separate components. Alternatively, one or more of these components 104, 108, 112 can be integrally formed as a single component rather than being discrete components. For example, in other embodiments, the electrically conductive portion can include or define the aesthetically colored portion, and/or the core can include or define the aesthetically colored portion.

With further reference to the illustrated embodiment 100 in FIGS. 1 through 3, the colored portion 112 is attached to both the core 104 and the electrically conductive portion 108. The electrically conductive portion 108 is disposed only partway around the core 104 such that its end portions 116 and 120 are spaced apart and non-overlapping. The end portions 116 and 120 of the electrically conductive portion 108 overlap and are engaged to the corresponding end portions 124, 128 of the aesthetically colored portion 112. In this exemplary manner, the end portions 116, 120 of the electrically conductive portion 108 allows the side of the EMI shield 100 on which the aesthetically colored portion 112 is disposed to remain electrically conductive even if the aesthetically colored portion 112 is itself electrically nonconductive.

The sizes (e.g., length, width, thickness) and shapes of the EMI shields 100, 200, 300, 400, 500, 600 and their respective components shown in FIGS. 1 through 12 are merely illustrative and should not be considered limiting. The sizes and shapes of the EMI shield and its components will depend on the particular application in which the EMI shield will be used.

By way of example only, the thickness of an EMI shield may be between about 2.0 mm (0.080 inches) or less and about 3.2 mm (0.125 inches) or more. Length and width of the EMI shield may be any suitable dimension, for example from about 38 mm (1.5 inches) or less to about 160 mm (6.25 inches) or more. The electrically conductive portion may have a thickness between about 0.1 mm (0.004 inches) or less and about 0.5 mm (0.02 inches) or more. The electrically conductive portion may overlap opposite edges of the aesthetically colored portion from between about 2.5 mm (0.10 inches) or less to about 6.4 mm (0.25 inches) or more. These ranges are considered exemplary in nature and specific dimensions for a particular application would depend on the material properties of the EMI shield components, the overall configuration of the EMI shield, the location tolerance of the connectors, and the electrical properties of the electrically conductive portion. Further, the thickness of the foam or other core material may vary as a function of location, so that the shield is thicker in one region than another to accommodate gaps of different thickness in the enclosure and connector locations. Accordingly, values outside these dimensional ranges are considered to be within the scope of the invention.

Further, the amount of the aesthetically colored portion that is exposed and visible to a user of an electronic device housing in which the EMI shield will be used can vary. For example, in FIG. 3, the electrically conductive portion 208 is wrapped around the core 204 and aesthetically colored portion 212 to a greater extent than what is shown in FIG. 1. In yet other embodiments, the electrically conductive portion may be disposed entirely around the sides of the shield with the aesthetically colored portion then being applied over and bonded to the electrically conductive portion.

One or more apertures or openings can be formed in an EMI shield to allow connection of support equipment or peripherals to the electronic equipment. These apertures or openings can include all sizes and shapes of holes, gaps, slits, openings, and other penetrations through the layers of the EMI shields, including open ended slots. Further, an aesthetically colored EMI shield can also be used effectively with elements other than connectors, such as cables and the like, when size and spatial location at installation can vary.

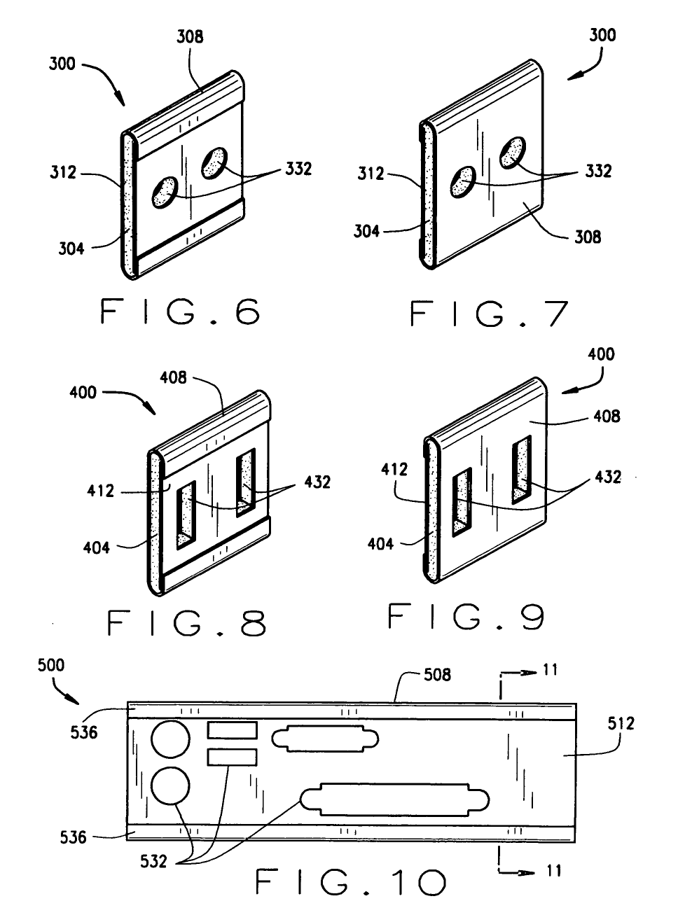

By way of example only, FIGS. 6 and 7 illustrate an exemplary EMI shield 300 that includes two generally circular openings 332 formed through the core 304, electrically conductive portion 308, and aesthetically colored portion 312.

FIGS. 8 and 9 illustrate an exemplary EMI shield 400 that includes two generally rectangular openings 432 formed through the core 404, electrically conductive portion 408, and aesthetically colored portion 412.

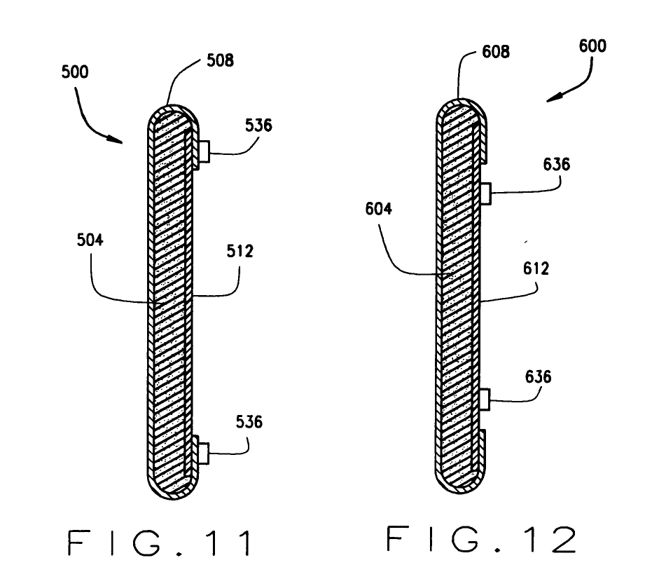

FIGS. 10 and 11 illustrate an exemplary EMI shield 500 that includes various sized and shaped openings 532 formed through the core 504, electrically conductive portion 508, and aesthetically colored portion 512. By way of example, these openings 532 can be used for connecting peripheral devices, such as a computer mouse, a computer monitor, a computer printer, and other peripherals. Accordingly, the EMI shield 500 can be particularly useful in shielding the cutouts, connector sockets, and gaps associated with an input/output (“I/O”) panel of a computer.

Optionally, adhesive strips (or other attachment means) may be attached to the electrically conductive portion 108 and/or to the aesthetically colored portion 112 to facilitate installation of the EMI shield 100 into a housing or enclosure. For example, FIG. 11 illustrates conductive adhesive strips 536 attached to the electrically conductive portion 508 to facilitate installation and also form a conductive path between the EMI shield 500 and the housing in which the EMI shield 500 is installed. FIG. 12 illustrates an exemplary EMI shield 600 that includes electrically nonconductive adhesive strips 636 attached to the aesthetically colored portion 612 (instead of the electrically conductive portion 608) to facilitate installation of the EMI shield 600 into a housing.

A wide range of materials, preferably resiliently compressible, can be used for the core of an EMI shield of the present invention. In one implementation, a fire retardant urethane foam is used for the core. Alternatively, other materials can be used for the core such as other types of urethanes, thermally formable foams, thermoplastic elastomer foams, silicones, gels, natural or synthetic rubbers, and gas filled bladders.

By using a resiliently compressible core material, various implementations provide EMI shields that are elastically compliant and resilient to compensate for variable gap widths and door operation, yet tough to withstand repeated door closure and connector installation without failing due to metal fatigue.

A wide range of materials can also be used for the aesthetically colored portion of an EMI shield of the present invention. In one implementation, the aesthetically colored portion includes a colored film that is laminated to the core. The colored film can be formed from a wide variety of materials including polyesters, polycarbonates (e.g., Lexan® polycarbonate, etc.), polymers, polyvinylchloride (PVC), among other suitable materials. In some implementations, the colored film may also have to satisfy certain rigidity and flame retardancy requirements.

Due to the limited amount of space in which EMI shields are commonly positioned, the aesthetically colored portion can be formed of a relatively thin colored film. In addition, the colored film can also be relatively flexible (e.g., more flexible that the core and/or the electrically conductive portion, etc). In various implementations, the colored film can also provide a smooth, flat surface on which indicia can be printed, labels may be bonded, or in which other markings may be embossed.

In various implementations, the aesthetically colored portion may be integral with the core. That is, the core can include or define the aesthetically colored portion. In which case, the material used for the aesthetically colored portion would be the same as that material used for the core. Likewise, other implementations can include the aesthetically colored portion being integral with the electrically conductive portion. That is, the electrically conductive portion can include or define the aesthetically colored portion. In which case, the material used for the aesthetically colored portion would be the same as that material used for the electrically conductive portion.

The electrically conductive portion of an EMI shield of the present invention can include all manner of electrically conductive structure capable of at least partially surrounding a resiliently compressible core, including metallized fabrics, metallic foils, metallic laminates, conductive polymers, flexible conductive ceramics, and the like. As used herein, the term metallized fabrics generally refers to and includes articles having one or more metal coatings disposed on woven, nonwoven, or open mesh carrier backings and equivalents thereof. Metallized fabrics are available in a variety of metal and fabric carrier backing combinations, such as copper on a nylon carrier, nickel-copper alloy on a nylon carrier, nickel on a polyester mesh carrier, and aluminum foil on a polyester mesh carrier. Other suitable metals include silver, tin, zinc, palladium, gold, and platinum. Electrically conductive paints could also be used, as well as metallic vapor depositions. The choice of material or structure for the electrically conductive portion may be guided, at least in part, by installation conditions for the particular EMI shield. For example, a particular metal might be chosen due to the composition of abutting body metal in the enclosure to avoid galvanic corrosion of the EMI shield which could increase electrical resistance and deteriorate electrical grounding performance.

Further, metallized tapes can also be used for the electrically conductive portion, for example, because their ease of application to the core as well as durability. One exemplary implementation employs a metallized fabric in tape form of suitable width backed with a thermally activated glue. The glue may cover substantially the entire backing or solely portions thereof, such as along the edges. Further, a metallized fabric may be used that includes one or more drain wires passing therethrough, for example, in a crisscross pattern, to further facilitate grounding.

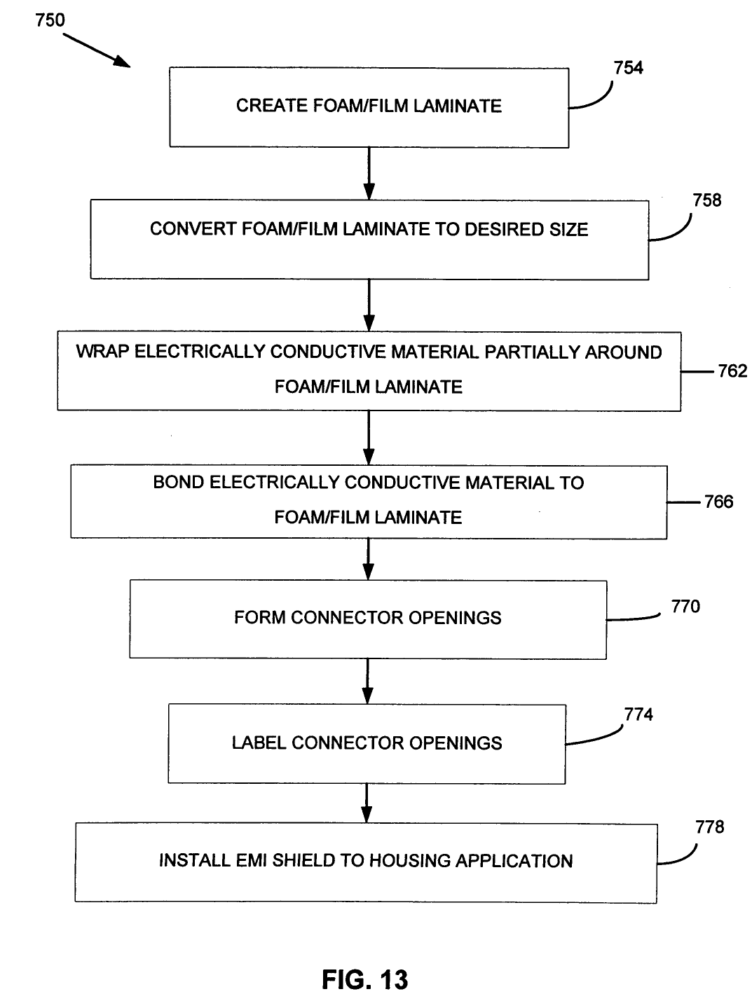

Aesthetically colored EMI shields of the invention can be made in various ways including continuous processes along a manufacturing line. Referring now to FIG. 13, a description will now be provided of one exemplary process 750 for making aesthetically colored EMI shields.

As shown in FIG. 13, operation 754 includes creating a foam/film laminate by coupling a colored film to a core material. The film and foam can each have a width of about sixty inches, although other sizes can also be employed.

In one embodiment, a roll of urethane foam is laminated on one surface with a colored film using a flame laminating process. Generally, a controlled flame can be applied to the surface of the foam which is to be laminated to the colored film. In response, the foam surface melts and reactivates the chemical elements of the foam surface. The colored film is applied to the melted foam surface, and pressure is applied such that the melted foam surface creates a bond with the colored film. Alternatively, other suitable processes can also be employed to form the foam/film laminate such as a heat lamination process, pressure lamination process, coating process, knife over roll process, nip roll process, corona treatment process, pressure sensitive adhesives, etc.

At operation 758, the foam/film laminate is cut or converted to the desired size, for example, by slitting, die cutting, crush cutting, etc. In one implementation, the foam/film laminate is rolled onto a spool, and then converted by way of a slitting process. One exemplary implementation slits the foam/film laminate to a width about equal to the nominal width of the finished EMI shield. The desired size will vary depending on the particular application in which the EMI shield will be used.

At operation 762, an electrically conductive material (e.g., metallized fabric, metallic foil, metallic foil laminate, etc.) is wrapped partially around the foam/film laminate. The extent to which the electrically conductive material is wrapped around the foam/film laminate can vary depending, at least in part, on how much of the colored film should remain exposed and not covered by the electrically conductive material. For example, in FIG. 3, the electrically conductive portion 208 is wrapped around the core 204 and aesthetically colored portion 212 to a greater extent than what is shown in FIG. 1.

With further reference to FIG. 13, operation 766 includes bonding the electrically conductive portion to the foam/film laminate. In one embodiment shown in FIG. 1, the end portions 116 and 120 of the electrically conductive portion 108 overlap and are engaged to the corresponding end portions 124 and 128 of the aesthetically colored portion 112. The electrically conductive material can be bonded to the colored film using various methods such as heated forming dies, adhesives (e.g., heat activated adhesives, flame retardant adhesives, pressure sensitive adhesives, etc.), among other suitable processes. In one implementation, a metallized fabric or other electrically conductive material in the form of a roll having an adhesive laminated along one side thereof is passed over a heated plate to thermally activate the adhesive. In some embodiments, the metallized fabric can also be bonded to the foam.

At operation 770 shown in FIG. 13, any number of connector openings can be formed in the EMI shield. By way of example only, the EMI shield may be passed through a rotary die cutter to form the connector openings in the EMI shield. Alternatively, other suitable processes can be employed to form the connector openings in one or more of the components of the EMI shield before, after, or as the components are coupled to one another.

At operation 774, a silk screening or other printing operation may be used to mark the aesthetically colored portion with indicia so as to label the connector openings for a type of connector or cable to be employed with a particular port. Alternatively, the aesthetically colored portion could be pre-printed.

In various embodiments, the EMI shield may not include any connector openings. In which case, operations 770 and 774 may be bypassed or skipped.

At operation 778, the EMI shield can be operatively engaged with an electronic equipment housing. For example, the EMI shield can be installed internally within or externally to the housing. Once installed, the EMI shield can not only be used for sealing the ingress and egress of EMI transmissions to and from electronic equipment within the housing, but also can provide an aesthetic feature as well.

In another form, the present invention provides methods of shielding against ingress and egress of electromagnetic energy relative to an electronic device housing or enclosure. In one implementation, the method generally includes coupling to the electronic device housing at least one EMI shield having an aesthetically colored portion such that the aesthetically colored portion is visible external to the housing. The aesthetically colored portion substantially reflects light having a frequency within a predetermined range so as to color coordinate (e.g., match the color of, contrast with the color of, etc.) the light being substantially reflected by adjacent external structure of the electronic device housing.

In another implementation, the method generally includes selecting a color from a plurality of colors for an aesthetically colored portion of at least one EMI shield, and coupling the EMI shield to the electronic device housing such that the aesthetically colored portion is visible external to the housing. In those implementations that include a plurality of EMI shields, the method can further include selecting a different color for the aesthetically colored portion of each of the EMI shields.

In yet another form, the present invention provides methods of customizing an electronic device housing. In one implementation, the method generally includes decorating the electronic device housing with at least one color-coordinated EMI shield coupled to the housing such that an aesthetically colored portion of the EMI shield is visible external to the housing. In various implementations, the method can also include selecting a color from a plurality of colors for the aesthetically colored portion of the at least one color-coordinated EMI shield. In those implementations that include a plurality of EMI shields, the method can further include selecting a different color for the aesthetically colored portion of each of the EMI shields.

Accordingly, various implementations can solve both EMI shielding and aesthetics requirements. For example, aspects of the invention allow for customization or personalization of electronic device housings by allowing a user to select a color for the aesthetically colored portion of the EMI shield so as to color-coordinate with the housing, or at least portion thereof, to which the EMI shield will be operatively engaged.

This can be especially advantageous given the increasing popularity of variously colored (e.g., red, blue, green, etc.) computer gaming consoles and in the Information Technology and Telecommunications where peripheral connections are commonly located in the view of the operator. With various implementations of the present invention, the aesthetically colored portion can be colored so as to at least substantially match or blend in with the color of the electronics enclosure so as to make the EMI shield less visible. In comparison, traditional EMI gaskets are commonly provided such that the natural metallic luster of the final plating component creates a metallic luster outline that is readily visible in contrast to the color of the electronics enclosure.

Various aspects of the invention can be used in a wide range of applications in which an aesthetically colored EMI shield might be desirable. Accordingly, the specific references to computer chassis herein should not be construed as limiting the scope of the invention to only one specific form/type of electronic device or housing. Further, the particular methods of manufacture and geometries disclosed herein are exemplary in nature and are not to be considered limiting. The method steps, processes, and operations described herein are not to be construed as necessarily requiring their performance in the particular order discussed or illustrated, unless specifically identified as an order or performance. It is also to be understood that additional or alternative steps may be employed. In addition, any one or more aspects of the invention may be implemented individually or in any combination with any one or more of the other aspects of the invention.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “top”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When describing elements, components, or features of the present invention or embodiments thereof, the articles “a”, “an”, “the”, and “said” are intended to mean that there are one or more of the elements, components, or features. The terms “comprising”, “including”, and “having” are intended to be inclusive and mean that there may be additional elements or features beyond those specifically described.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A method of shielding against ingress and egress of electromagnetic energy relative to an electronic device housing, the method comprising coupling to the electronic device housing at least one electromagnetic interference (EMI) shield having an aesthetically colored portion such that the aesthetically colored portion is visible external to the housing, the aesthetically colored portion substantially reflecting light having a frequency within a predetermined range so as to color coordinate with light being substantially reflected by adjacent external structure of the electronic device housing.

2. The method of claim 1, wherein the method includes selecting a color from a plurality of colors for the aesthetically colored portion of the at least one EMI shield.

3. The method of claim 2, wherein selecting a color includes selecting a color that matches a color of the light being substantially reflected by the adjacent external structure of the electronic device housing.

4. The method of claim 2, wherein selecting a color includes selecting a color that contrasts with a color of the light being substantially reflected by the adjacent external structure of the electronic device housing.

5. The method of claim 1, wherein the at least one EMI shield includes a plurality of EMI shields, and wherein the method includes selecting a different color for the aesthetically colored portion of each said EMI shield.

6. A method of shielding against ingress and egress of electromagnetic energy relative to an electronic device housing, the method comprising selecting a color from a plurality of colors for an aesthetically colored portion of at least one electromagnetic interference (EMI) shield, and coupling the EMI shield to the electronic device housing such that the aesthetically colored portion is visible external to the housing.

7. The method of claim 6, wherein selecting a color includes selecting a color so as to coordinate with a color of external structure of the electronic device housing adjacent to the EMI shield.

8. The method of claim 7, wherein selecting a color includes selecting a color matching the color of the external structure of the electronic device housing adjacent to the EMI shield.

9. The method of claim 7, wherein selecting a color includes selecting a color contrasting with the color of the external structure of the electronic device housing adjacent to the EMI shield.

10. The method of claim 6, wherein the at least one EMI shield includes a plurality of EMI shields, and wherein the method includes selecting a different color for the aesthetically colored portion of each said EMI shield.

11. A method of customizing an electronic device housing, the method comprising decorating the electronic device housing with at least one color-coordinated electromagnetic interference (EMI) shield coupled to the housing such that an aesthetically colored portion of the EMI shield is visible external to the housing.

12. The method of claim 11, wherein the method includes selecting a color from a plurality of colors for the aesthetically colored portion of the at least one color-coordinated EMI shield.

13. The method of claim 12, wherein selecting a color includes selecting a color so as to coordinate with a color of external structure of the electronic device housing adjacent to the EMI shield.

14. The method of claim 13, wherein selecting a color includes selecting a color matching the color of the external structure of the electronic device housing adjacent to the EMI shield.

15. The method of claim 13, wherein selecting a color includes selecting a color contrasting with the color of the external structure of the electronic device housing adjacent to the EMI shield.

16. The method of claim 11, wherein the at least one color-coordinated EMI shield includes a plurality of EMI shields, and wherein the method includes selecting a different color for the aesthetically colored portion of each said EMI shield.
